(19) United States
(12) Patent Application Publication
(10) Pub. No.: US 2025/0359403 A1
(43) Pub. Date: Nov. 20, 2025

(54) PACKAGE STRUCTURE

(71) Applicant: Lextar Electronics Corporation, Hsinchu City (TW)

(72) Inventors: Ming YANG, Hsinchu City (TW); Shu-Wei CHEN, Hsinchu (TW); Kuo-Wei HUANG, Hsinchu City (TW)

(21) Appl. No.: 19/187,776

(22) Filed: Apr. 23, 2025

(30) Foreign Application Priority Data
May 16, 2024 (TW) 113118105

(51) Int. Cl. H10H 20/857; H10H 20/853

(52) U.S. Cl. CPC H10H 20/857; H10H 20/853

(57) ABSTRACT

A package structure is provided. The package structure includes multiple lead frames. Each lead frame has a recess and a die-bonding surface. The package structure also includes an insulating portion that covers the lead frames and fills the recesses of the lead frames. The insulating portion also fills the space between the lead frames. The insulating portion defines an accommodation space and has multiple openings that expose the die-bonding surfaces of the lead frames. The package structure further includes an optoelectronic element and an encapsulant. The optoelectronic element is disposed within the accommodation space and is electrically connected to the die-bonding surfaces of the lead frames, and the encapsulant is disposed within the accommodation space and covers the optoelectronic element.

### CROSS REFERENCE TO RELATED APPLICATIONS

This application claims priority of Taiwan Patent Application No. 113118105, filed on May 16, 2024, the entire content of which is incorporated by reference herein.

### Technical Field

The disclosure relates to a package structure, and in particular, it relates to a package structure that includes an optoelectronic element.

### BACKGROUND

### Description of the Related Art

With the development of optoelectronic technology, optoelectronic elements have been widely applied in various electronic devices. For example, semiconductor materials that include group III and group V elements can be applied to various optoelectronic elements, such as light-emitting chips (e.g., light-emitting diodes or laser diodes), light-absorbing chips (e.g., photodetectors or solar cells), and power devices (e.g., switches or rectifiers), which can be used in fields such as lighting, medical, display, automotive, communication, sensing, and power systems. Although existing optoelectronic elements generally meet a variety of needs, they are not entirely satisfied in all respects and still require further improvement.

### SUMMARY

In the embodiments of the present disclosure, the package structure includes multiple lead frames and an insulating portion. The lead frames have recesses and die-bonding surfaces, and the insulating portion fills the recesses and has multiple openings that expose the die-bonding surfaces. This configuration allows the conductive elements (e.g., metal solder) to be confined within fixed areas when the optoelectronic element is bonded to the lead frames. Consequently, the electrodes of the optoelectronic element may be stably bonded to the lead frames, effectively enhancing bonding strength and reducing heat accumulation.

According to some embodiments of the present disclosure, a package structure is provided. The package structure includes a base. The base includes multiple lead frames. Each lead frame has a recess and a die-bonding surface. The base also includes an insulating portion that covers the lead frames and fills the recesses of the lead frames. The insulating portion also fills the space between the lead frames. The insulating portion defines an accommodation space and has multiple openings that expose the die-bonding surfaces of the lead frames. The package structure further includes an optoelectronic element and an encapsulant. The optoelectronic element is disposed within the accommodation space and is electrically connected to the die-bonding surfaces of the lead frames, and the encapsulant is disposed within the accommodation space and covers the optoelectronic element.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a partial cross-sectional view illustrating the package structure according to some embodiments of the present disclosure.

FIG. 2 is a partial top view illustrating the package structure according to some embodiments of the present disclosure.

FIG. 3 is a partial top view illustrating the lead frames according to some embodiments of the present disclosure.

FIG. 4 is a partial top view illustrating the die-bonding surfaces of the lead frames and the insulating portion according to some embodiments of the present disclosure.

FIG. 5 is an enlarged (partial cross-sectional) view illustrating the lead frames and the insulating portion 14 according to some embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

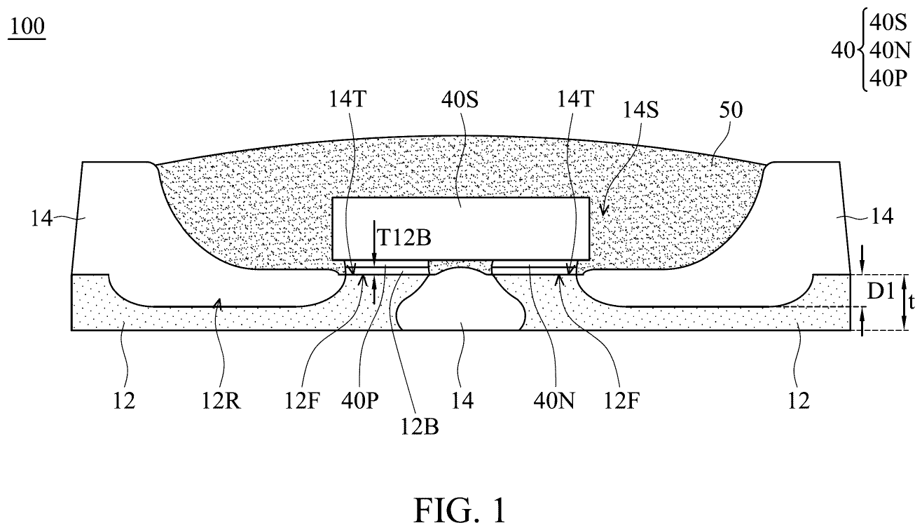

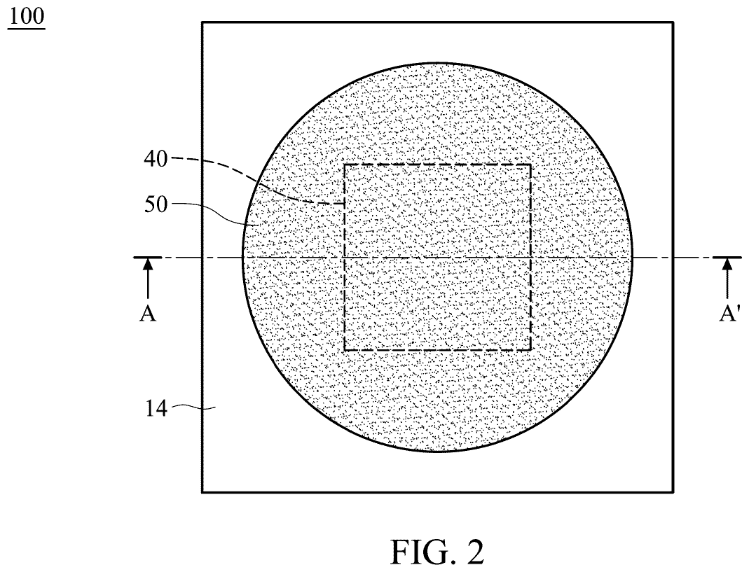

FIG. 1 is a partial cross-sectional view illustrating the package structure 100 according to some embodiments of the present disclosure. FIG. 2 is a partial top view illustrating the package structure 100 according to some embodiments of the present disclosure. For example, FIG. 1 may be a cross-sectional view taken along line A-A′ of FIG. 2, but the present disclosure is not limited thereto. It should be noted that some components of the package structure 100 have been omitted in FIG. 1 and FIG. 2 for the sake of brevity. Moreover, FIG. 1 and FIG. 2 may not correspond to each other completely.

Referring to FIG. 1 and FIG. 2, in some embodiments, the package structure 100 includes a base 10, an optoelectronic element 40, and an encapsulant 50. Specifically, the optoelectronic element 40 and the encapsulant 50 are disposed on the base 10, and the encapsulant 50 covers the optoelectronic element 40.

In some embodiments, the base 10 includes multiple lead frames 12 and an insulating portion 14. The insulating portion 14 covers the lead frames 12 and defines an accommodation space 14S. Specifically, each lead frame 12 has a recess 12R and a die-bonding surface 12F. The insulating portion 14 covers the multiple lead frames 12 and fills the recesses 12R and the space between adjacent lead frames 12. The insulating portion 14 has multiple openings 14T, and each opening 14T respectively exposes the corresponding die-bonding surface 12F.

In some embodiments, the lead frame 12 may include conductive materials, such as metals, but the present disclosure is not limited thereto. For example, the metals may be gold (Au), nickel (Ni), platinum (Pt), palladium (Pd), iridium (Ir), titanium (Ti), chromium (Cr), tungsten (W), aluminum (Al), copper (Cu), similar materials, alloys of the foregoing, or combinations thereof, but the present disclosure is not limited thereto.

In some embodiments, the insulating portion 14 may include insulating materials, such as polyimide (PI), epoxy resin, silicone resin, other suitable materials, or combinations thereof. In some embodiments, fillers may be added to the insulating material of the insulating portion 14 to provide reflective or light-absorbing effects. The fillers may include, for example, titanium oxide (TiOₓ), silicon oxide (SiOₓ), carbon black, pigments, other suitable materials, or combinations thereof. The insulating portion 14 may be formed by coating, molding, other suitable methods, or combinations thereof, but the present disclosure is not limited thereto.

As shown in FIG. 1, in some embodiments, the depth D1 of the recess 12R of the lead frame 12 is substantially between ⅓ to ½ of the thickness t of the lead frame 12. Here, the thickness t of the lead frame 12 may be defined as the maximum thickness of the lead frame 12 in the normal (vertical) direction. This ratio may make the parts subsequently formed (e.g., the insulating portion 14) easier to fully fill in the recess 12R, thereby preventing moisture penetration. Moreover, the recess 12R formed by wet etching may have a smooth surface, which may prevent gas accumulating at the bottom of the recess 12R to cause voids during the filling process, and effectively prevent contaminants from entering the package structure 100 through the voids.

As shown in FIG. 1 and FIG. 2, in some embodiments, the optoelectronic element 40 is disposed within the accommodation space 14S and electrically connected to the die-bonding surfaces 12F of the lead frames 12. In some embodiments, the optoelectronic element 40 includes a light-emitting element, a light-receiving element, or a logic element. For example, the light-emitting element may include a light-emitting diode (LED) or a laser diode (LD), the light-receiving element may include a photodiode (PD), and the logic element may include a phototransistor or a photo integrated circuit (photo IC). In some embodiments, the optoelectronic element 40 includes a semiconductor stack 40S and multiple electrodes 40P, 40N. The electrodes 40P, 40N are on the same side of the semiconductor stack 40S and connected to the die-bonding surfaces 12F of the lead frames 12 via conductive elements 12B. For example, the electrodes 40P, 40N may have one or more metal bumps, and the conductive elements 12B may include metal solder (which may include metal particles and flux). The bumps of the electrodes 40P, 40N may be connected to the die-bonding surfaces 12F of the lead frames 12 via metal solder, but the present disclosure is not limited thereto.

In some embodiments, the die-bonding surfaces 12F of the lead frames 12 are within the orthogonal projection of the optoelectronic element 40 on the lead frames 12. In other words, the die-bonding surfaces 12F of the lead frames 12 are entirely beneath the optoelectronic element 40. Furthermore, in some embodiments, at least one of the top view areas of the electrodes 40P, 40N of the optoelectronic element 40 may be substantially the same as at least one of the top view areas of the die-bonding surfaces 12F of the lead frames 12, but the present disclosure is not limited thereto.

In some embodiments, the semiconductor stack 40S may include semiconductor materials such as silicon, germanium, nitrides, phosphides, arsenides, other suitable materials, or combinations thereof. In some embodiments, when the optoelectronic element 40 is a light-emitting element, the optoelectronic element 40 may emit visible light or invisible light as needed. For example, visible light may include violet, blue, green, or red light, and invisible light may include ultraviolet or far-infrared light, but the present disclosure is not limited thereto.

The electrodes 40P, 40N may include conductive materials such as metals, nitrides, oxides, similar materials, or combinations thereof, but the present disclosure is not limited thereto. For example, the metals may be gold (Au), nickel (Ni), platinum (Pt), palladium (Pd), iridium (Ir), titanium (Ti), chromium (Cr), tungsten (W), aluminum (Al), copper (Cu), similar materials, alloys of the foregoing, or combinations thereof. The nitrides may include titanium nitride (TiN), and the oxides may include indium tin oxide (ITO) or indium zinc oxide (IZO), but the present disclosure is not limited thereto.

In some embodiments, the encapsulant 50 is disposed within the accommodation space 14S and covers the optoelectronic element 40. For example, the encapsulant 50 may form a hemispherical package body that encapsulates the optoelectronic element 40, but the present disclosure is not limited thereto. In some embodiments, the encapsulant 50 may include wavelength conversion substances such as phosphors or quantum dots (QDs), but the present disclosure is not limited thereto.

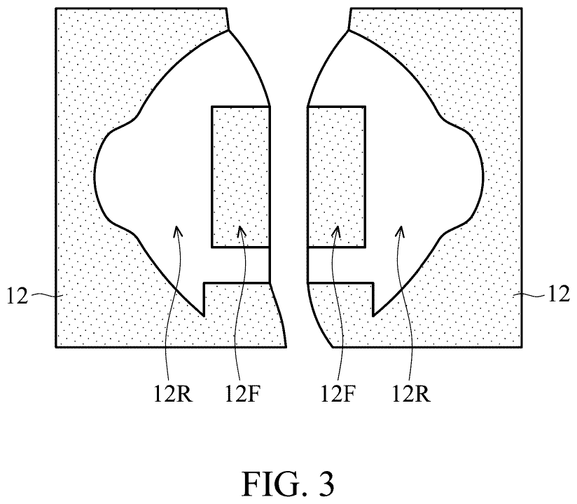

FIG. 3 is a partial top view illustrating the lead frames 12 according to some embodiments of the present disclosure. As shown in FIG. 1 and FIG. 3, in some embodiments, the die-bonding surface 12F is an island-shaped conductive plane. For example, wet etching may be performed on a conductive metal sheet to create the recess 12R and form one or more die-bonding surfaces 12F.

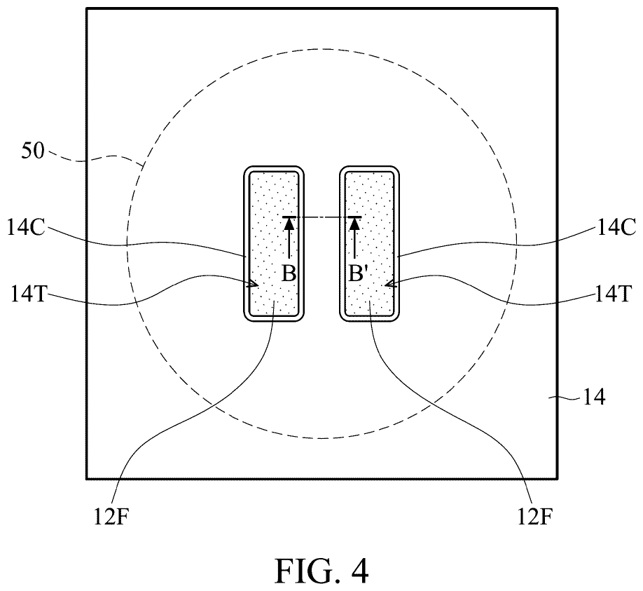

FIG. 4 is a partial top view illustrating the die-bonding surfaces 12F of the lead frames 12 and the insulating portion 14 according to some embodiments of the present disclosure. Referring to both FIG. 1 and FIG. 4, in some embodiments, the insulating portion 14 further includes multiple connecting surfaces 14C, and each connecting surface 14C is adjacent to the corresponding opening 14T. In other words, each connecting surface 14C is adjacent to the die-bonding surface 12F exposed by the corresponding opening 14T. In some embodiments, in a top view (e.g., the top view shown in FIG. 4), at least one connecting surface 14C surrounds the corresponding die-bonding surface 12F.

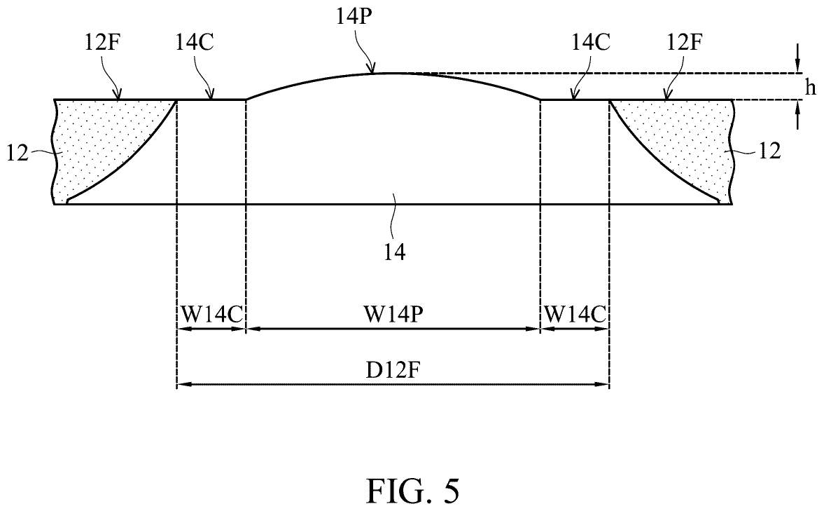

FIG. 5 is an enlarged (partial cross-sectional) view illustrating the lead frames 12 and the insulating portion 14 according to some embodiments of the present disclosure. In some embodiments, there is a protruding surface 14P between two adjacent die-bonding surfaces 12F. Specifically, there are two adjacent connecting surfaces 14C between the two adjacent die-bonding surfaces 12F, and the protruding surface 14P is between the two adjacent connecting surfaces 14C. That is, the connecting surfaces 14C are between the protruding surface 14P and the die-bonding surfaces 12F. In some embodiments, the connecting surfaces 14C are substantially coplanar with the die-bonding surfaces 12F of the lead frames 12. In this embodiment, the protruding surface 14P is connected to the die-bonding surfaces 12F via the connecting surfaces 14C, but the present disclosure is not limited thereto.

In some embodiments, the total width of the protruding surface 14P and the connecting surfaces 14C in the horizontal direction (i.e., width W14C+width W14P+width W14C) is less than or equal to the distance D12F between two adjacent lead frames 12. If the total width of the protruding surface 14P and the connecting surfaces 14C in the horizontal direction (i.e., width W14C+width W14P+width W14C) is greater than the distance D12F between two adjacent lead frames 12, it may cause the optoelectronic element 40 can't be evenly mounted on the lead frames 12. This unevenness may lead to uneven solder on both sides of the optoelectronic element 40, resulting in poor thermal conductivity and heat concentration.

Additionally, in some embodiments, the ratio of the distance h (see FIG. 5) between the highest point of the protruding surface 14P and the die-bonding surface 12F of the lead frame 12 in the vertical direction to the thickness T12B (see FIG. 1) of the conductive element 12B in the vertical direction is substantially between ⅓ and 1.

In the embodiments of the present disclosure, the insulating portion 14 surrounds and covers the lead frames 12 to form a reflector cup, and the island-shaped conductive plane of the lead frames 12 (i.e., the die-bonding surface 12F) is exposed at the bottom of the reflector cup to fix the optoelectronic element 40. The area of the exposed island-shaped conductive plane (i.e., the die-bonding surface 12F) may be close to the area of the electrodes 40N, 40P of the optoelectronic element 40. In a cross-sectional view (e.g., the cross-sectional view of FIG. 1 or FIG. 5), the insulating portion 14 between the die-bonding surfaces 12F has a protruding surface 14P that is higher than the die-bonding surfaces 12F and the connecting surfaces 14C. The protruding surface 14P is separated from the die-bonding surfaces 12F, and the protruding surface 14P may be connected to the die-bonding surfaces 12F via the connecting surfaces 14C, which are parallel to the die-bonding surfaces 12F.

The protruding surface 14P may, for example, confine the flux in the solder to the die-bonding surfaces 12F during reflow process, preventing the conductive elements 12B connected to each other due to the flowing flux with melting metal particles, leading to electrical short circuits and product failure. Moreover, because the solder is confined to the die-bonding surfaces 12F, the flux may effectively wet the electrodes 40N, 40P of the optoelectronic element 40 and the die-bonding surfaces 12F, allowing the liquid metal to fully bond the electrodes 40N, 40P and the die-bonding surfaces 12F. When the metal is cool down and solidified, the distribution of the solidified metal is also more uniform.

In a top view (e.g., the top view shown in FIG. 4), the die-bonding surfaces 12F of the lead frames 12 are surrounded by the connecting surfaces 14C of the insulating portion 14, and the connecting surfaces 14C are substantially conformal with the die-bonding surfaces 12F. If the optoelectronic element 40 shifts during bonding to the lead frames 12, the connecting surfaces 14C of the insulating portion 14 may act as a buffer region to prevent the die-bonding surfaces 12F from being covered by the protruding surface 14P of the insulating portion 14, thereby reducing the size of the die-bonding surfaces 12F and affecting the solder bonding area.

As noted above, the embodiments of the present disclosure use multiple openings in the insulating portion of the base to conformally expose multiple die-bonding surfaces within the accommodation space, making the exposed conductive area approximately the same area as the optoelectronic element's electrodes. This confines the solder between the optoelectronic element's electrodes and the die-bonding surfaces, improving die bonding yield and heat dissipation efficiency. Furthermore, the embodiments of the present disclosure include protruding surface between adjacent die-bonding surfaces to limit solder flow during die bonding, reducing the likelihood of component failure due to electrical connection between the optoelectronic element's electrodes.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A package structure, comprising:
a base, comprising:
a plurality of lead frames, wherein each of the lead frames has a recess and a die-bonding surface; and
an insulating portion covering the lead frames and filling the recesses of the lead frames and a space between the lead frames, wherein the insulating portion defines an accommodation space and has a plurality of openings that expose the die-bonding surfaces of the lead frames;
an optoelectronic element disposed within the accommodation space and electrically connected to the die-bonding surfaces of the lead frames; and
an encapsulant disposed within the accommodation space and covering the optoelectronic element.

2. The package structure as claimed in claim 1, wherein the die-bonding surfaces of the lead frames are within an orthogonal projection of the optoelectronic element on the lead frames.

3. The package structure as claimed in claim 1, wherein a depth of the recess is between ⅓ to ½ of a thickness of each of the lead frames.

4. The package structure as claimed in claim 1, wherein the insulating portion comprises a plurality of connecting surfaces respectively adjacent to the corresponding one of the openings.

5. The package structure as claimed in claim 4, wherein in a top view, one of the connecting surfaces surrounds one of the die-bonding surfaces exposed by the corresponding one of the openings.

6. The package structure as claimed in claim 5, wherein a top view shape of the one of the connecting surfaces is conformal with that of the one of the die-bonding surfaces.

7. The package structure as claimed in claim 4, wherein in a cross-sectional view, at least one of the connecting surfaces is coplanar with one of the die-bonding surfaces exposed by the corresponding one of the openings.

8. The package structure as claimed in claim 4, wherein in a cross-sectional view, one of the connecting surfaces is a flat plane.

9. The package structure as claimed in claim 4, wherein in a cross-sectional view, the insulating portion comprises a protruding surface between two adjacent connecting surfaces.

10. The package structure as claimed in claim 9, wherein in the cross-sectional view, a total width of the two adjacent connecting surfaces and the protruding surface therebetween in a horizontal direction is less than or equal to a distance between two adjacent die-bonding surfaces.

11. The package structure as claimed in claim 1, wherein in a cross-sectional view, the insulating portion comprises a protruding surface between two adjacent die-bonding surfaces.

12. The package structure as claimed in claim 11, wherein in the cross-sectional view, the protruding surface is higher than the die-bonding surfaces.

13. The package structure as claimed in claim 11, wherein in the cross-sectional view, the protruding surface has a dome shape.

14. The package structure as claimed in claim 11, wherein in the cross-sectional view, the insulating portion comprises a connecting surface between the protruding surface and one of the two adjacent die-bonding surfaces.

15. The package structure as claimed in claim 14, wherein the protruding surface is connected to the one of the two adjacent die-bonding surfaces via the connecting surface therebetween.

16. The package structure as claimed in claim 14, wherein in the cross-sectional view, the connecting surface is lower than the protruding surface.

17. The package structure as claimed in claim 11, wherein the optoelectronic element comprises a semiconductor stack and a plurality of electrodes, and the electrodes are on the same side of the semiconductor stack and connected to the die-bonding surfaces of the lead frames via a plurality of conductive elements.

18. The package structure as claimed in claim 17, wherein a ratio of a distance between the highest point of the protruding surface and one of the die-bonding surfaces in a vertical direction to a thickness of one of the conductive elements in the vertical direction is between ⅓ and 1.

19. The package structure as claimed in claim 1, wherein one of the recesses has a smooth surface.

20. The package structure as claimed in claim 1, wherein one of the die-bonding surfaces is an island-shaped conductive plane.
